(19) United States
(12) Patent Application Publication
(10) Pub. No.: US 2026/0344452 A1
(43) Pub. Date: Oct. 29, 2026

(54) STORAGE APPARATUS AND IDENTIFIER MANAGEMENT SYSTEM AND METHOD THEREFOR

(71) Applicant: SK hynix Inc., Gyeonggi-do (KR)

(72) Inventor: Ji Hoon HWANG, Gyeonggi-do (KR)

(21) Appl. No.: 19/319,676

(22) Filed: Sep. 4, 2025

(30) Foreign Application Priority Data
Apr. 23, 2025 (KR) 10-2025-0052934

(51) Int. Cl. H10W 46/00; H10W 70/60

(52) U.S. Cl. CPC H10W 46/00; H10W 70/60; H10W 46/401

(57) ABSTRACT

A storage apparatus is provided that can identify a corresponding electronic device and manage a history of the electronic device without labeling of product information. The storage apparatus includes a controller and a storage medium configured to operate based on control of the controller, and store a storage identifier (ID) generated based on a serial number of the controller.

### CROSS-REFERENCE TO RELATED APPLICATIONS

The present application claims priority under 35 U.S.C. § 119(a) to Korean Patent Application Number 10-2025-0052934, filed on Apr. 23, 2025, which is incorporated herein by reference in its entirety.

### BACKGROUND

### 1. Technical Field

Various embodiments may generally relate to an electronic device, and more particularly, to a storage apparatus and an identifier management system and method therefor.

### 2. Related Art

A semiconductor package such as a storage apparatus may be released with labeling of product information for a packaged electric device on the outside of the package. The semiconductor package manufacturer or seller may track various histories for manufacturing processes through a unique identifier included in the product information.

However, it is difficult to secure space for labelling the product information in a small semiconductor package, and thus it may be impossible to understand a process history of the corresponding product without this information.

### SUMMARY

Embodiments are provided to a storage apparatus capable of identifying a corresponding electronic device and managing a history of the electronic device without labeling of product information for the electronic device, and an identifier management system and method therefor.

In accordance with an embodiment of the present disclosure, a storage apparatus may be provided. The storage apparatus may include a controller and a storage medium configured to operate based on control of the controller, and store a storage identifier (ID) generated based on a serial number of the controller.

In accordance with an embodiment of the present disclosure, an identifier management system may be provided. The identifier management system may a serial number acquisition circuit configured to acquire a controller serial number from a storage apparatus; and an identifier setup circuit. The identifier setup circuit is configured to generate a storage identifier (ID) based on the controller serial number, and transfer the storage ID in the storage apparatus.

In an embodiment of the present disclosure, an identifier management method may be an operating method of an identifier management system which communicates with a storage apparatus. The method may include acquiring, by the identifier management system, a controller serial number from the storage apparatus; generating, by the identifier management system, a storage identifier (ID) based on the controller serial number; and storing, by the identifier management system, the storage ID in the storage apparatus.

According to the present technology, a process history of an electronic device may be managed without labelling of an identifier of the packaged electronic device.

These and other features, aspects, and embodiments are described in more detail below.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a diagram illustrating a configuration of a storage apparatus according to an embodiment of the present disclosure;

FIG. 2 is a diagram explaining a configuration of a controller serial number according to an embodiment of the present disclosure;

FIG. 3 is a diagram explaining a physical interface of a storage apparatus according to an embodiment of the present disclosure;

FIG. 4 is a diagram illustrating a configuration of an identifier management system according to an embodiment of the present disclosure;

FIG. 5 is a diagram explaining configurations of a controller serial number and a storage identifier according to an embodiment of the present disclosure; and

FIG. 6 is a flowchart explaining an identifier management method according to an embodiment of the present disclosure.

### DETAILED DESCRIPTION

Various embodiments of the present teachings are described in detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present teachings as defined in the appended claims.

The present teachings are described herein with reference to cross-section and/or plan illustrations of idealized embodiments of the present teachings. However, embodiments of the present teachings should not be construed as limiting the present teachings. Although a few embodiments of the present teachings are shown and described, it will be appreciated by those of ordinary skill in the art that changes may be made in these embodiments without departing from the principles and spirit of the present teachings.

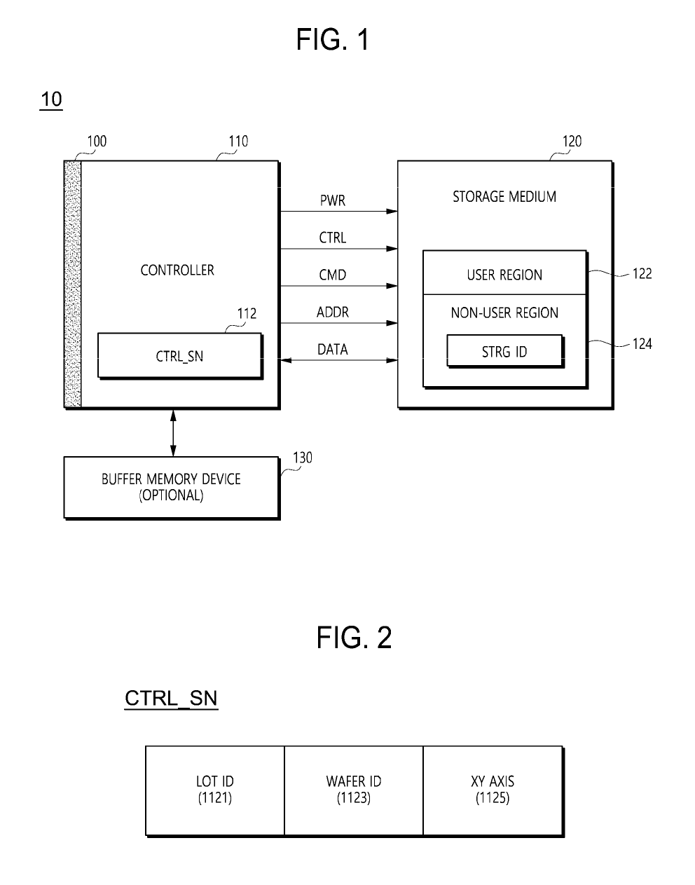

FIG. 1 is a configuration diagram of a storage apparatus 10 according to an embodiment.

Referring to FIG. 1, the storage apparatus 10 may include a controller 110 and a storage medium 120. In an embodiment, the storage apparatus 10 may, optionally, include a buffer memory device 130. In another embodiment, the storage apparatus 10 may not include the buffer memory device 130.

In an embodiment, the storage apparatus 10 illustrated in FIG. 1 may have a configuration in which the controller 110 and the storage medium 120 are mounted on a single package. In another embodiment, the storage apparatus 10 may have a configuration that the buffer memory device 130 is further optionally mounted on the single package.

The storage apparatus 10 may communicate with an external apparatus through an external apparatus interface 100.

The controller 110 may include a nonvolatile storage region 112. A controller serial number CTRL_SN may be stored in the nonvolatile storage region 112. In an embodiment, the nonvolatile storage region 112 may include an e-fuse memory device.

The storage medium 120 may include a volatile memory device and a nonvolatile memory device. The nonvolatile memory device may be implemented using a memory device selected from among various types of nonvolatile memory devices such as an electrically erasable and programmable read only memory (EEPROM), a NAND flash memory, a NOR flash memory, a phase-change random access memory (PRAM), a resistive RAM (ReRAM), a ferroelectric RAM (FRAM), and a spin transfer torque magnetic RAM (STT-MRAM).

The storage medium 120 may perform an erase operation, a write operation, a read operation, or the like according to control of the controller 110. To perform such an operation, the storage medium 120 may receive power PWR from the controller 110 through a power line and receive a control signal CTRL from the controller 110 through a control line.

The storage medium 120 may receive a command CMD, an address ADDR, and data DATA from the controller 110 through input/output lines to perform the write operation. The storage medium 120 may receive the command CMD and the address ADDR from the controller 110 to perform the erase operation or the read operation. The storage medium 120 may provide data DATA read through the read operation to the controller 110.

The storage medium 120 may include a user region 122 and a non-user region 124.

Data provided from an external apparatus may be stored in the user region 122.

A boot code for booting of the storage apparatus 10, a firmware code, and various parameters required for an operation of the controller 110 may be stored in the non-user region 124.

In some embodiments, a storage identifier STRG_ID may be stored in the non-user region 124 of the storage medium 120 included in the storage apparatus 10 according to an embodiment of the present technology.

The storage identifier STRG_ID may be unique information assigned to the storage apparatus 10 and may be generated based on the controller serial number CTRL_SN.

The controller serial number CTRL_SN may be manufacturing history tracking information of the controller 110.

FIG. 2 is a diagram explaining a configuration of a controller serial number CTRL_SN according to an embodiment of the present disclosure.

Referring to FIG. 2, the controller serial number CTRL_SN includes a lot identifier (LOT ID) 1121, a wafer identifier (WAFER ID) 1123, and a chip coordinate (XY AXIS) 1125.

Semiconductor chips such as the controller 110 may be manufactured in wafer units, and a plurality of wafers may constitute a lot LOT as one production unit.

The lot identifier (LOT ID) 1121 may be a unique number for identifying the production unit. The chips manufactured in the same process, for example, the controllers 110 may have the same lot identifier (LOT ID) 1121.

The wafer identifier (WAFER ID) 1123 may be a number for identifying wafers included in the lot LOT.

A single wafer may include hundreds to thousands of chips. The chip coordinate (XY AXIS) 1125 may be information indicating a position of an individual chip on the wafer, for example, a position of the controller 110.

Accordingly, the controller serial number CTRL_SN may be uniquely set to each controller 110.

The storage identifier STRG_ID may be generated based on the controller serial number CTRL_SN uniquely assigned to each controller 110 and stored in the non-user region 124 of the storage medium 120. In some embodiments, the storage identifier STRG_ID of the storage apparatus 10 may be read to perform production history tracking, defect analysis, process improvement, and the like of the storage apparatus 10, and thus the manufacturing yield of the storage apparatus 10 may be improved.

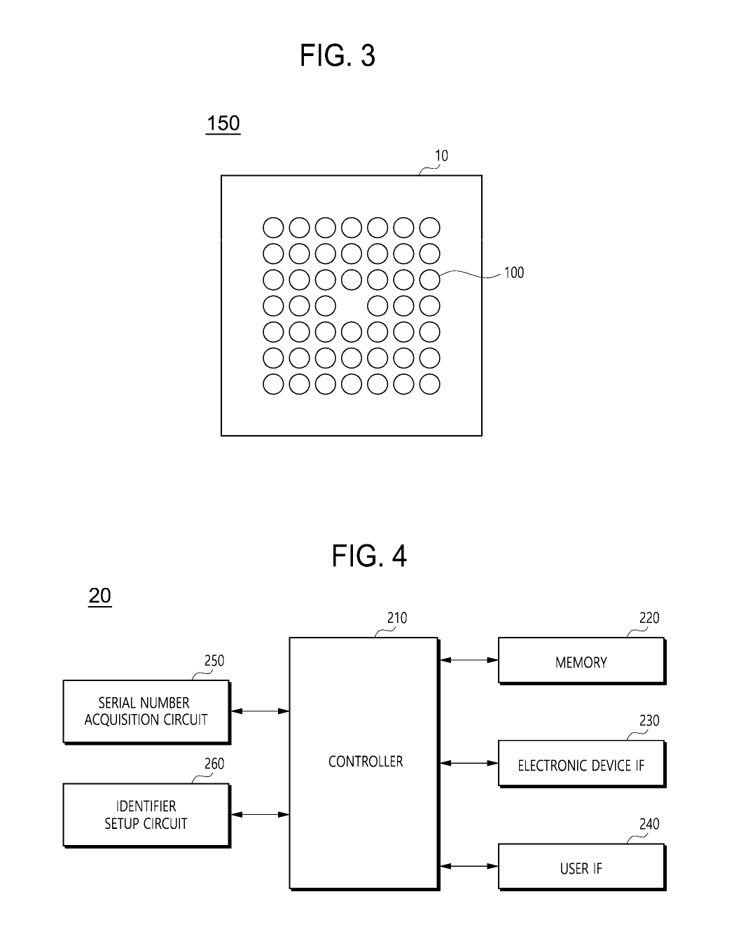

FIG. 3 is a diagram illustrating an explanation of a physical interface of a storage apparatus according to an embodiment of the present disclosure.

FIG. 3 is a bottom view of a package 150 of the storage apparatus 10 illustrated in FIG. 1. An external apparatus interface 100 may be formed on a bottom of the package 150. In some embodiments, the external apparatus interface 100 may be implemented with a ball grid array (BGA).

The storage apparatus 10 using the BGA as the external apparatus interface 100 may be manufactured with the ultra-small package 150 having a size of (10~16) mm * (13~20) mm.

Because it is difficult to label the product information on the ultra-small package 150, the storage identifier STRG_ID generated based on the controller serial number CTRL_SN may be stored in the storage medium 120 built in the package 150. In some embodiments, the storage identifier STRG_ID may be read to track and manage the history of the package 150.

FIG. 4 is a configuration diagram of an identifier management system 20 according to an embodiment of the present disclosure.

Referring to FIG. 4, the identifier management system 20 may include a controller 210, a memory 220, an electronic device interface (IF) 230, a user IF 240, a serial number acquisition circuit 250, and an identifier setup circuit 260.

The controller 210 may be a central processing unit (CPU) configured to control an overall operation of the identifier management system 20, and may be configured in a form in which software and hardware executing the software are combined. In an embodiment, the controller 210 may be configured to execute an operating system (OS) to manage each hardware configuration and control processing of various types of programs such as an application which is executed in the identifier management system 20, firmware, and middleware.

The memory 220 may include a main storage device configured to store a program to be executed in the controller 210, data, or a processing result of the controller 210 and an auxiliary storage device configured to store a program to be executed in the controller 210 and data, such as a disc.

The electronic device IF 230 may provide an environment that may enable the identifier management system 20 to communicate with an electronic device, for example, the storage apparatus 10 through the external apparatus interface 100 illustrated in FIGS. 1 and 3.

The user IF 240 may include an input device and an output device. The input device may include at least one of a keyboard, a mouse, and a touch device. The output device may include at least one of an image display device such as a monitor and a speaker.

The serial number acquisition circuit 250 may read a serial number of the electronic device connected to the electronic device IF 230.

In an embodiment, the serial number acquisition circuit 250 may read the controller serial number CTRL_SN stored in the controller 110 (for example, CTRL_SN 112, as illustrated in FIG. 1) of the storage apparatus 10.

The identifier setup circuit 260 may generate the identifier of the electronic device based on the controller serial number CTRL_SN read in the serial number acquisition circuit 250 and store the generated identifier in the electronic device.

In an embodiment, the identifier setup circuit 260 may generate the storage identifier STRG_ID based on the controller serial number CTRL_SN read from the storage apparatus 10 through the electronic device IF 230. The identifier setup circuit 260 may store the storage identifier STRG_ID in the non-user region 124 of the storage medium 120 through the electronic device IF 230.

In an embodiment, the firmware configured to control the hardware constituting the storage apparatus 10 to operate the storage apparatus 10 may be stored in the non-user region 124 of the storage medium 120. The identifier setup circuit 260 may store the storage identifier STRG_ID in a specific region of the storage firmware, for example, a device identifier serial number field, but this is not limited thereto.

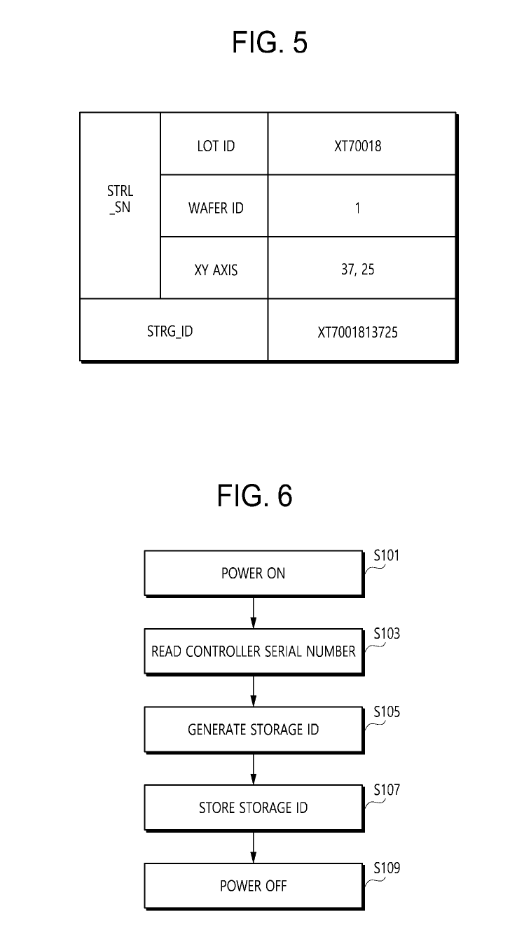

FIG. 5 is a diagram illustrating an explanation of configurations of a controller serial number CTRL_SN and a storage identifier STRG_ID according to an embodiment.

Referring to FIG. 5, the controller serial number CTRL_SN includes XT70018 as the lot identifier LOT ID, 1 as the wafer identifier WAFER ID, and (37, 25) as the chip coordinate XY AXIS.

As the serial number acquisition circuit 250 reads the controller serial number CTRL_SN, the identifier setup circuit 260 may combine the lot identifier LOT ID=XT70018, the wafer identifier WAFER ID=1, and the chip coordinate XY AXIS = (37, 25) to generate the storage identifier STRG_ID=XT7001813725.

The storage identifier STRG_ID=XT7001813725 may be stored in the storage medium 120 and read from the storage medium 120, when required (e.g., if necessary). Accordingly, the history of the storage apparatus 10 may be tracked without labeling the product information on a restricted surface of the package 150 of the storage apparatus 10.

FIG. 6 is a flowchart of an identifier management method according to an embodiment of the present disclosure.

Referring to FIG. 6, when the electronic device such as the storage apparatus 10 is mounted on the identifier management system 20 and powered on (S101), the identifier management system 20 may read the controller serial number CTRL_SN of the controller 110 included in the storage apparatus 10 (S103).

The identifier management system 20 may generate the storage identifier STRG_ID based on the controller serial number CTRL_SN (S105).

The identifier management system 20 may transfer the storage identifier STRG_ID to the storage medium 120 (S107). In an embodiment, the storage medium 120 ma store the storage identifier STRG_ID. The storage identifier STRG_ID may be stored in the non-user region 124 of the storage medium 120 or a specific field of the firmware stored in the non-user region 124.

The identifier management system 20 may power off the storage apparatus 10 after storing the storage identifier STRG_ID (S109).

As the unique identifier of the product packaged in the package of the electronic device is stored in the storage medium within the package, the history of the electronic device may be managed without attaching of the label on the outside of the package.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A storage apparatus comprising:
a controller; and
a storage medium configured to operate based on control of the controller, and store a storage identifier (ID) generated based on a serial number of the controller.

2. The storage apparatus of claim 1, wherein the serial number is stored in the controller.

3. The storage apparatus of claim 1, wherein the serial number includes a lot ID, a wafer ID, and a chip coordinate.

4. The storage apparatus of claim 1, wherein the storage medium includes a user region and a non-user region, and
the storage ID is stored in the non-user region.

5. The storage apparatus of claim 1, further comprising a ball grid array (BGA) interface configured to interface between the controller and an external apparatus.

6. An identifier management system comprising:
a serial number acquisition circuit configured to acquire a controller serial number from a storage apparatus; and
an identifier setup circuit configured to
generate a storage identifier (ID) based on the controller serial number, and
transfer the storage ID in the storage apparatus.

7. The identifier management system of claim 6, wherein
the serial number acquisition circuit is configured to read the controller serial number from a controller of the storage apparatus including the controller and a storage medium.

8. The identifier management system of claim 6, wherein the controller serial number includes a lot ID, a wafer ID, and a chip coordinate.

9. The identifier management system of claim 6, wherein
the identifier setup circuit is configured to store the storage ID in a non-user region of the storage medium, which includes a nonvolatile memory device divided into a user region and the non-user region.

10. The identifier management system of claim 6, further comprising an electronic device interface coupled to a ball grid array (BGA) interface of the storage apparatus.

11. An operating method of an identifier management system which communicates with a storage apparatus, the method comprising:
acquiring, by the identifier management system, a controller serial number from the storage apparatus;
generating, by the identifier management system, a storage identifier (ID) based on the controller serial number; and
storing, by the identifier management system, the storage ID in the storage apparatus.

12. The method of claim 11, wherein
the acquiring, by the identifier management system, of the controller serial number includes reading the controller serial number from a controller of the storage apparatus including the controller and a storage medium.

13. The method of claim 11, wherein the controller serial number includes a lot ID, a wafer ID, and a chip coordinate.

14. The method of claim 11, wherein
the storing, by the identifier management system, of the storage ID includes storing the storage ID in a non-user region of the storage medium, which includes a nonvolatile memory device divided into a user region and the non-user region.

15. The method of claim 11, further comprising: interfacing with a ball grid array (BGA) interface of the storage apparatus.
